(19) United States
(12) Patent Application Publication
(10) Pub. No.: US 2008/0217708 A1
(43) Pub. Date: Sep. 11, 2008

(54) Integrated passive cap in a system-in-package

(75) Inventors: Russ Reisner, Newbury Park, CA (US); Steve X. Liang, San Diego, CA (US); Sandra L. Petty-Weeks, Newport Beach, CA (US); Howard Chen, Diamond Bar, CA (US); Ryan C. Lee, Torrance, CA (US)

Correspondence Address: FARJAMI & FARJAMI LLP, 26522 LA ALAMEDA AVENUE, SUITE 360, MISSION VIEJO, CA, 92691, US

(73) Assignee: SKYWORKS SOLUTIONS, INC., WOBURN, MA (US)

(21) Appl. No.: 12/006,945

(22) Filed: Jan. 8, 2008

Related U.S. Application Data
(60) Provisional application No. 60/906,170, filed on Mar. 9, 2007.

(51) Int. Cl. H01L 29/84; H01L 21/52

(52) U.S. Cl. 257/416; 438/125; 257/E29.324; 257/E21.5

(57) ABSTRACT

According to an exemplary embodiment, a system-in-package includes at least one semiconductor die situated over a package substrate. The system-in-package further includes a wall structure situated on the at least one semiconductor die. The system-in-package further includes an integrated passive cap situated over the wall structure, where the integrated passive cap includes at least one passive component. The wall structure and the integrated passive cap form an air cavity over the at least one semiconductor die. The system-in-package can further include at least one bond pad situated on a cap substrate. The at least one bond pad on the cap substrate of the integrated passive cap can be electrically connected to a substrate bond pad on the package substrate.

The present application claims the benefit of and priority to a pending provisional patent application entitled “Integrated Passive Stacking for RFICs and MEMS in a System-in-Package,” Ser. No. 60/906,170 filed on Mar. 9, 2007. The disclosure in that pending provisional application is hereby incorporated fully by reference into the present application.

### BACKGROUND OF THE INVENTION

1. Field of the Invention

The present invention generally relates to the field of electrical devices and components. More particularly, the invention relates to the fabrication and packaging of semiconductors, passive components, and MEMS devices.

2. Background Art

A system-in-package (SIP) can be utilized in electronic devices, such as cellular phones, to provide a high level of circuit integration in a single molded package. The SIP can include one or more semiconductor dies, such as radio frequency integrated circuits (RFICs) and/or microelectromechanical systems (MEMS) devices, which can be combined with one or more passive components on a package substrate, such as a multilayer laminate substrate. The SIP can also provide an air cavity for an RFIC or MEMS device that includes, for example, a bulk acoustic wave (BAW) filter or a surface acoustic wave (SAW) filter.

In one conventional approach, an air cavity can be created in an SIP by forming a dome made from a polymer, silicon, and/or glass over a semiconductor die, which can be an RFIC or a MEMS device. In another conventional approach, an air cavity can be created in an SIP by forming polymer walls on a semiconductor die, such as an RFIC or MEMS device, and forming a silicon cap on the polymer walls. However, in the conventional approaches discussed above, the dome or cap can significantly increase manufacturing costs while serving only a mechanical function, i.e., as a mechanical package component used to create an air cavity.

### SUMMARY OF THE INVENTION

Integrated passive cap in a system-in-package, substantially as shown in and/or described in connection with at least one of the figures, as set forth more completely in the claims.

### BRIEF DESCRIPTION OF THE DRAWINGS

FIG. 1 shows a cross-sectional view of an exemplary system-in-package including an exemplary integrated passive cap, in accordance with one embodiment of the present invention.

FIG. 2 shows a cross-sectional view of an exemplary system-in-package including an exemplary integrated passive cap, in accordance with one embodiment of the present invention.

FIG. 3 shows a top view of an exemplary integrated passive cap including exemplary spiral inductors, in accordance with one embodiment of the present invention.

FIG. 4 shows a top view of an exemplary integrated passive cap including exemplary via winding inductors, in accordance with one embodiment of the present invention.

FIG. 5 shows a top view of an exemplary integrated passive cap including exemplary wire bond winding inductors, in accordance with one embodiment of the present invention.

### DETAILED DESCRIPTION OF THE INVENTION

The present invention is directed to an integrated passive cap in a system-in-package. The following description contains specific information pertaining to the implementation of the present invention. One skilled in the art will recognize that the present invention may be implemented in a manner different from that specifically discussed in the present application. Moreover, some of the specific details of the invention are not discussed in order to not obscure the invention. The specific details not described in the present application are within the knowledge of a person of ordinary skill in the art.

The drawings in the present application and their accompanying detailed description are directed to merely exemplary embodiments of the invention. To maintain brevity, other embodiments of the invention which use the principles of the present invention are not specifically described in the present application and are not specifically illustrated by the present drawings.

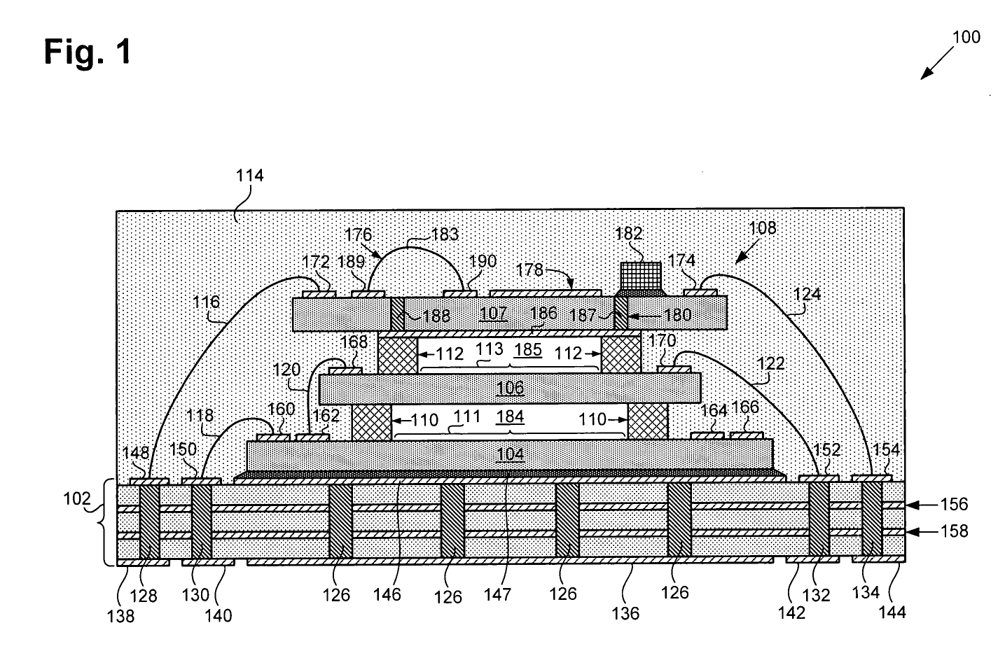

FIG. 1 shows a cross-sectional view of SIP (system-in-package) 100 in accordance with one embodiment of the present invention. Certain details and features have been left out of FIG. 1 that are apparent to a person of ordinary skill in the art. SIP 100, which is an overmolded package, includes package substrate 102, semiconductor dies 104 and 106 (hereinafter referred to simply as “dies 104 and 106”), integrated passive cap 108, wall structures 110 and 112, overmold 114, and wire bonds 116, 118, 120, 122, and 124 (hereinafter “wire bonds 116 through 124”) and wire bond 183. Package substrate 102 includes electrically and thermally conductive vias 126, 128, 130, 132, and 134 (hereinafter “conductive vias 126 through 134”), ground contact 136, input/output (I/O) pads 138, 140, 142, and 144 (hereinafter “I/O pads 138 through 144”), die attach pad 146, substrate bond pads 148, 150, 152, and 154, and metal layers 156 and 158. Die 104 includes die bond pads 160, 162, 164, and 166, die 106 includes die bond pads 168 and 170, and integrated passive cap 108 includes cap substrate 107, cap bond pads 172 and 174, wire bond winding inductor 176, spiral inductor 178, via winding inductor 180, and surface mount component 182.

SIP 100 can be utilized in an electronic device, such as, for example, a cellular phone. In one embodiment, an SIP can include only one semiconductor die, such as die 104 or 106, a package substrate, such as package substrate 102, an integrated passive cap, such as integrated passive cap 108, and a wall structure, such as wall structure 110 or 112, where the integrated passive cap and the wall structure form an air gap over the die.

As shown in FIG. 1, die attach pad 146 and substrate bond pads 148 through 154 are situated on the top surface of package substrate 102, conductive vias 126 through 134 extend through package substrate 102, and ground contact 136 and I/O pads 138 through 144 are situated on the bottom surface of package substrate 102. Substrate bond pads 148 through 154 are electrically connected to I/O pads 138 through 144 by respective conductive vias 128, 130, 132, and 134 and die attach pad 146 is electrically connected to ground contact 136 by conductive vias 126. Die attach pad 146, substrate bond pads 148 through 154, ground contact 136, and I/O pads 128 through 134 can comprise copper or other suitable metal or metal stack and can be fabricated in a manner known in the art. I/O pads 138 through 144 can be, for example, land grid array (LGA) I/O pads. Conductive vias 126 can provide thermal and electrical connectivity between die attach pad 146 and ground contact 136. Package substrate 102 can be, for example, a multilayer laminate or ceramic substrate.

Also shown in FIG. 1, metal layers 156 and 158, which are interconnect metal layers, are situated in package substrate 102. In the present embodiment, package substrate 102 can comprise four metal layers, i.e., metal layers 156 and 158, which are situated within package substrate 102, and top and bottom metal layers. In other embodiments, package substrate 102 can comprise less than four or more than four metal layers.

Also shown in FIG. 1, die 104 is situated on die attach pad 146 on package substrate 102. Die 104 can be attached to die attach pad 146 by die attach adhesive 147, which can be, for example, a conductive or a nonconductive epoxy. Die 104 can be an RFIC or a MEMS device and can include a BAW filter, a SAW filter, or other MEMS structure or device that requires an air cavity. Further shown in FIG. 1, die bond pads 160, 162, 164 and 166 are situated on the active surface of die 104. Die bond pad 160 is electrically connected to substrate bond pad 150 by wire bond 118 and die bond pad 162 is electrically connected to die bond pad 168 on die 106 by wire bond 120. Die bond pads 164 and 166 can also be electrically connected to die bond pads on die 106 or substrate bond pads on package substrate 102 by wire bonds (not shown in FIG. 1).

Also shown in FIG. 1, wall structure 110 is situated on the active surface of die 104 and surrounds portion 111 of die 104, which can include a device that requires an air cavity, such as a BAW filter, a SAW filter, or other MEMS device or MEMS structure. Wall structure 110 can comprise a polymer, such as an epoxy, or other type of suitable material. In one embodiment, wall structure 110 can comprise SU-8, which is an epoxy-based photoresist from MicroChem Corp. Wall structure 110 can be formed by, for example, applying a polymer, such as a spin-on polymer or a dry film polymer, over die 104 and appropriately patterning the polymer so as to form a wall structure around portion 111 of die 104. In one embodiment, wall structure 110 can comprise a number of wall-enclosed cells, where each wall-enclosed cell is situated over and surrounds a BAW resonator or other component or device for which an individual overlying air cavity is desired.

Further shown in FIG. 1, die 106 is situated over wall structure 110 such that the bottom surface of die 106 forms a cap on wall structure 110. Die 106 can be attached to wall structure 110 by utilizing a suitable adhesive or bonding material. Die 106 can be an RFIC or a MEMS device and can include a BAW filter, a SAW filter, or other MEMS structure or device that requires an air cavity. The bottom surface of die 106 in and wall structure 110 form air cavity 184 over portion 111 of die 104, which can include a device that requires an air cavity, such as a BAW or SAW filter, or other MEMS device or structure. Also shown in FIG. 1, die bond pads 168 and 170 are situated on the active surface of die 106 and can be electrically connected to die bond pad 162 and substrate bond pad 152 by respective wire bonds 120 and 122. Further shown in FIG. 1, wall structure 112 is situated on the active surface of die 106 and surrounds portion 113 of die 106, which can include a device that requires an air cavity, such as a BAW filter, a SAW filter, or other MEMS device or structure. Wall structure 112 is substantially similar in composition and formation to wall structure 110.

Also shown in FIG. 1, integrated passive cap 108 is situated over wall structure 112 such that the bottom surface of integrated passive cap 108 covers wall structure 120 and forms a cap on the wall structure. Integrated passive cap 108 can be attached to wall structure 112 by utilizing a suitable adhesive or bonding material. The bottom surface of integrated passive cap 108 and wall structure 112 form air cavity 185 over portion 113 of die 104, which can include a device that requires an air cavity, such as a BAW or SAW filter or other MEMS device or structure. Integrated passive cap 108 includes cap substrate 107, which can comprise, for example, a semiconductor material, such as silicon or gallium arsenide (GaAs), glass, an organic laminate material, or a ceramic material. Cap substrate 107, which forms a carrier for passive components, such as spiral inductor 178 and surface mount component 182, can be fabricated by utilizing semiconductor technology. In one embodiment, cap substrate 107 can be fabricated by utilizing printed circuit board (PCB) technology to achieve a low manufacturing cost. In another embodiment, cap substrate 107 can be fabricated by utilizing low temperature co-fired ceramic (LTCC) technology.

Further shown in FIG. 1, wire bond winding inductor 176 is situated on the top surface of cap substrate 107 and includes wire bonds, such as wire bond 183, cap bond pads, such as cap bond pads 189 and 190, as well as metal lines (not shown in FIG. 1), which are formed on the top surface of cap substrate 107. Wire bond 183 is electrically connected between cap bond pads 189 and 190 so as to form a wire bond winding of wire bond inductor 176. The wire bonds utilized in wire bond inductor 176 can comprise, for example, gold. Wire bond winding inductor 176 can have a high quality factor (Q).

Also shown in FIG. 1, spiral inductor 178 is situated on the top surface of cap substrate 107 and comprises a metal conductor having a spiral shape. Further shown in FIG. 1, via winding inductor 180 is situated on the top and bottom surfaces of cap substrate 107 and is also situated cap substrate 107. Via winding inductor 180 includes metal lines that are situated on the bottom surface of cap substrate 107, such as metal line 186, metal lines that are situated on the top surface of cap substrate 107 (not shown in FIG. 1), and conductive vias that extend through cap substrate 107, such as conductive vias 187 and 188. Conductive vias 187 and 188 and metal line 186, which is electrically connected between conductive vias 187 and 188, form a portion of a winding of via winding inductor 180.

Integrated passive cap 108 can also include a solenoid inductor (not shown in FIG. 1), which can comprise a metal conductor that spirals downward from the top surface of cap substrate 107 through one or more metal layers. The portions of the solenoid inductor that are formed in the metal layers within cap substrate 107 can be electrically connected to each other by conductive vias. Also shown in FIG. 1, surface mount component 182 is situated on the top surface of cap substrate 107 and can comprise a passive component, such as a surface mount resistor, capacitor, or inductor. Surface mount component 182 can be attached to the top surface of cap substrate 107 by solder or an adhesive material as known in the art. In other embodiments, integrated passive cap 108 can comprise one or more wire bond winding inductors, spiral inductors, via winding inductors, or solenoid inductors and/or one or more surface mount components. Further shown in FIG. 1, overmold 114 encapsulates integrated passive cap 108, dies 104 and 106, package substrate 102, wire bonds 116 through 124 and wire bond 183, and can comprise epoxy or other suitable molding compound.

In a conventional SIP (system-in-package), passive components, such as inductors, capacitors, and resistors, are typically formed on a package substrate that also houses a semiconductor die, which increases the footprint of the conventional SIP. In contrast, passive components that would conventionally be situated on the package substrate of the SIP are situated on and/or in an overlying integrated passive cap, which reduces size of the package substrate. Thus, by forming an integrated passive cap to house passive components that would otherwise be housed on the package substrate, the present invention advantageously achieves an SIP having a reduced footprint compared to a conventional SIP.

Also, in a conventional SIP, an air cavity is typically formed over a die, such as an RFIC or MEMS device, by forming polymer walls on the die and forming a cap on the walls. However, in the conventional SIP formation of the cap can significantly increase package assembly cost while only serving the mechanical function of forming the air cavity. In contrast, the present invention utilizes an integrated passive cap, which includes integrated passive components, to form an air cavity. By integrating passive components with an integrated passive cap that is also utilized to form an underlying air cavity, the invention advantageously reduces material costs and package assembly costs.

Additionally, in the invention's SIP, one or more dies and an integrated passive cap, which can include one or more passive components, can be vertically stacked over a package substrate to provide one or more air cavities, thereby advantageously achieving an SIP that provides increased volume efficiency and a minimized package footprint. Moreover, the invention's integrated passive cap can include small size passive components that are capable of high performance.

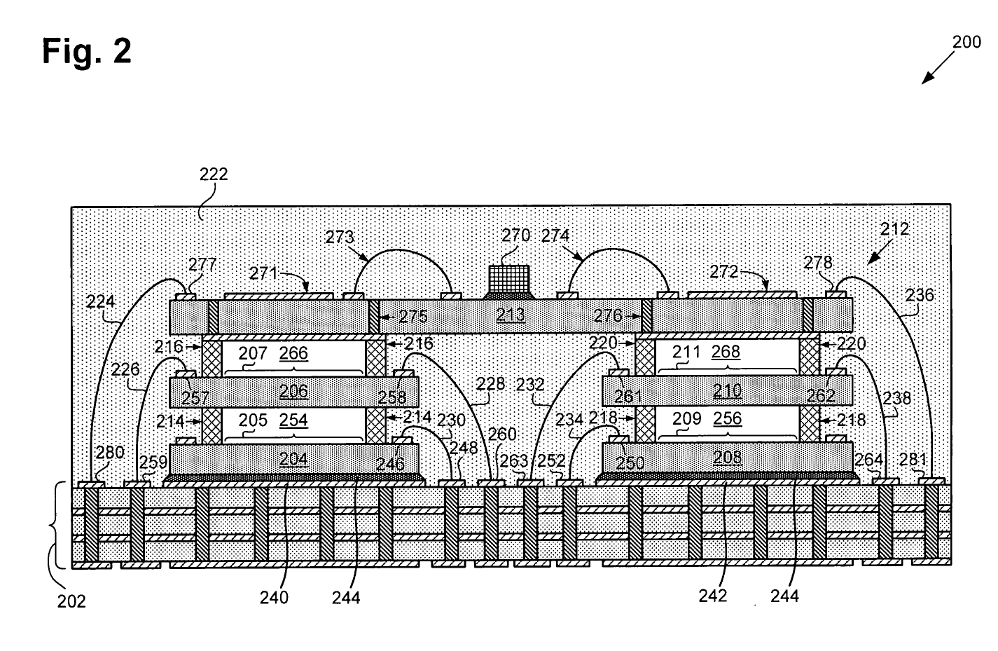

FIG. 2 shows a cross-sectional view of SIP (system-in-package) 200 in accordance with one embodiment of the present invention. Certain details and features have been left out of FIG. 2 that are apparent to a person of ordinary skill in the art. SIP 200, which is an overmolded package, includes package substrate 202, semiconductor dies 204, 206, 208, and 210 (hereinafter referred to simply as “dies 204, 206, 208, and 210”), integrated passive stacking cap 212 (hereinafter referred to simply as “integrated passive cap 212”), wall structures 214, 216, 218, and 220, overmold 222, and wire bonds 224, 226, 228, 230, 232, 234, 236, and 238 (hereinafter “wire bonds 224 through 238”) and wire bonds 273 and 274. In SIP 100 in FIG. 1, a single die (i.e. die 104) is attached to a die attach pad on the top surface of package substrate 102, whereas in two dies (i.e. dies 204 and 208) are attached to respective die attach pads on the top surface of package substrate 202 in SIP 200. To accommodate the additional die, package substrate 202 provides more surface area than package substrate 102 and requires an additional die attach pad and ground contact and additional conductive vias, I/O pads, and substrate bond pads than package substrate 102. However, package substrate 202 is substantially similar in composition and formation to package substrate 102. Also, the I/O pads, ground contacts, and conductive vias of package substrate 202 are substantially similar in composition and formation to the respective I/O pads, ground contact, and conductive vias of package substrate 102. Thus, to preserve brevity, the I/O pads, ground contacts, and conductive vias in package substrate 202 are not discussed in detail in the present application.

As shown in FIG. 2, dies 204 and 208 are situated over respective die attach pads 240 and 242 on the top surface of package substrate 202. Dies 204 and 208 can be attached to respective die attach pads 240 and 242 by die attach adhesive 244, which can be a conductive or nonconductive epoxy or other suitable adhesive material. Each of dies 204 and 208 can be an RFIC or a MEMS device and can include a BAW filter, a SAW filter, or other MEMS structure or device that requires an air cavity. In one embodiment, dies 204 and 208 can form a duplexer filter, wherein each of dies 204 and 208 comprise a BAW filter. Die 204 includes die bond pad 246, which can be electrically connected to substrate bond pad 248 by wire bond 230, and die 208 includes die bond pad 250, which can be electrically connected to substrate bond pad 252 by wire bond 234.

Also shown in FIG. 2, wall structure 214 is situated on the active surface of die 204 and surrounds portion 205 of die 204, and wall structure 218 is situated on the active surface of die 208 and surrounds portion 209 of die 208. Portion 205 of die 204 and portion 209 of die 208 can include a device that requires an air cavity, such as a BAW filter, a SAW filter, or other MEMS device or structure. Wall structures 214 and 218 are substantially similar in composition and formation to wall structure 110 in SIP 100 in FIG. 1. Further shown in FIG. 2, die 206 is situated over wall structure 214 so as to form a cap on wall structure 214 and die 210 is situated over wall structure 218 so as to from a cap on wall structure 218. Dies 206 and 208 can be attached to respective wall structures 214 and 218 by utilizing a suitable adhesive or bonding material.

Each of dies 206 and 210 can be an RFIC or a MEMS device and can include a BAW filter, a SAW filter, or other MEMS structure or device that requires an air cavity. The bottom surface of die 206 and wall structure 214 form air cavity 254 over portion 205 of die 204 and the bottom surface of die 210 and wall structure 218 form air cavity 256 over portion 209 of die 208. Die 206 includes die bond pads 257 and 258, which are electrically connected to substrate bond pads 259 and 260 by respective wire bonds 226 and 228, and die 210 includes die bond pads 261 and 262, which are electrically connected to substrate bond pads 263 and 264 by respective wire bonds 232 and 238.

Also shown in FIG. 2, wall structure 216 is situated on the active surface of die 206 and surrounds portion 207 of die 206, and wall structure 220 is situated on the active surface of die 210 and surrounds portion 211 of die 210. Portion 207 of die 206 and portion 211 of die 210 can include a device that requires an air cavity, such as a BAW filter, a SAW filter, or other MEMS structure. Wall structures 216 and 220 are substantially similar in composition and formation to wall structure 110 in SIP 100 in FIG. 1.

Further shown in FIG. 2, integrated passive cap 212 is situated over wall structures 216 and 220 so as to form respective caps on wall structures 216 and 220. Integrated passive cap 212 can be attached to respective wall structures 214 and 218 by utilizing a suitable adhesive or bonding material. The bottom surface of integrated passive cap 212 and wall structure 216 form air cavity 266 over portion 207 of die 206 and the bottom surface of integrated passive cap 212 and wall structure 220 form air cavity 268 over portion 211 of die 210. Thus, in the embodiment of the invention in FIG. 2, a common integrated passive cap, i.e., integrated passive cap 212, is utilized to form two air gaps, i.e., air gaps 266 and 268. Integrated passive cap 212 includes cap substrate 213, which can comprise, for example, a semiconductor, such as silicon or gallium arsenide, glass, an organic laminate material, or a ceramic material, and can include multiple metal layers. In one embodiment, cap substrate 213 can include one metal layer, which can be situated on the top surface of the substrate. Cap substrate 213 is substantially similar in composition and formation as cap substrate 107 in integrated passive cap 108 in FIG. 1.

Integrated passive cap 212 further includes surface mount component 270, spiral inductors 271 and 272, wire bond winding inductors 273 and 274, and via winding inductors 275 and 276. Surface mount component 270 is situated on the top surface of integrated passive cap 212 and can comprise a passive component, such as a surface mount resistor, capacitor, or inductor. Spiral inductors 271 and 272 and wire bond winding inductors 273 and 274 are situated on the top surface of integrated passive cap 212. Spiral inductors 271 and 272 are substantially similar in composition and formation to spiral inductor 178 in FIG. 1 and wire bond winding inductors 273 and 274 are substantially similar in composition and formation to wire bond winding inductor 183 in FIG. 1. Via winding inductors 275 and 276 are situated on the top and bottom surfaces of integrated passive cap 212, extend through cap substrate 213 of integrated passive cap 212, and are substantially similar in composition and formation to via winding inductor 180 in FIG. 1.

Integrated passive cap 212 can further include one or more solenoid inductors, which are not shown in FIG. 2. In other embodiments, integrated passive cap 212 can include different combinations of spiral inductors, wire bond winding inductors, via winding inductors, and solenoid inductors and can also include more than one surface mount component. Integrated passive cap 212 further includes cap bond pads 277 and 278, which are electrically connected to substrate bond pads 280 and 281 by respective wire bonds 224 and 236. Further shown in FIG. 1, overmold 222 encapsulates integrated passive cap 212, dies 204, 206, 208, and 210, package substrate 202, and wire bonds 224 through 238 and wire bonds 273 and 274 and can comprise epoxy or other suitable molding compound material.

By utilizing integrated passive cap 212, the embodiment of the invention's SIP in FIG. 2 provides similar advantages as the embodiment of the invention's SIP in FIG. 1 as discussed above. Also, by utilizing a common integrated passive cap to cover (i.e. to form a lid) on wall structures situated on two dies, the embodiment of the invention in FIG. 2 advantageously utilizing one integrated passive cap to form a separate air cavity for each die. Additionally, the common integrated passive cap utilized in the embodiment of the invention's SIP in FIG. 2 has a greater surface area than the integrated passive cap in the embodiment of the invention's SIP in FIG. 1, which allows the common integrated passive cap to include more components. Furthermore, one common integrated passive cap is less expensive to place in the invention's SIP compared to the cost of placing two separate integrated passive caps, which advantageously reduces SIP manufacturing cost.

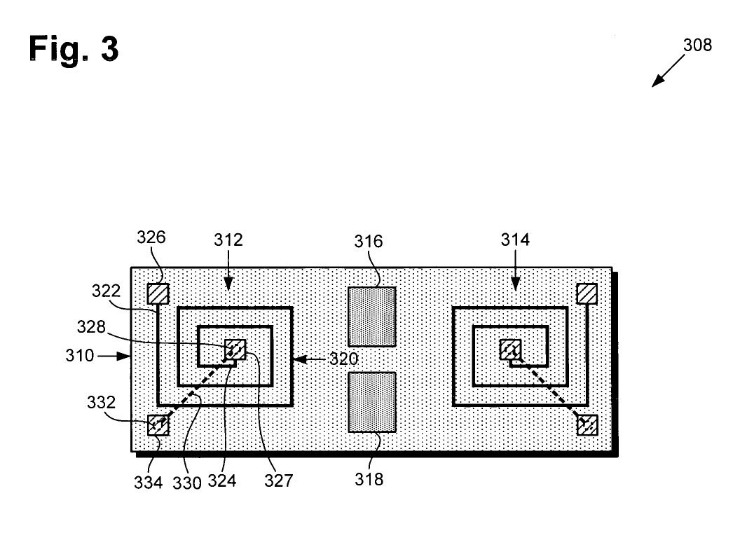

FIG. 3 shows a top view of integrated passive cap 308 in accordance with one embodiment of the present invention. Integrated passive cap 308 is an exemplary embodiment of the invention's integrated passive cap, such as integrated passive cap 108 in FIG. 1 or integrated passive cap 212 in FIG. 2. Integrated passive cap 308 includes cap substrate 310, spiral inductors 312 and 314, and surface mount components 316 and 318. As shown in FIG. 3, spiral inductors 312 and 314 and surface mount components 316 and 318 are situated on the top surface of cap substrate 310. Cap substrate 310 is substantially similar in composition and formation to cap substrate 107 in FIG. 1. Spiral inductor 312 comprises metal line 320, which has ends 322 and 324 and a spiral shape. End 322 of metal line 320 is connected to cap bond pad 326, which forms a first terminal of spiral inductor 312. End 324 of metal line 320 is connected to metal pad 327, which is connected to conductive via 328. Conductive via 328 is coupled by metal line 330, which is situated on the bottom surface of cap substrate 310, and conductive via 332 to cap bond pad 334, which forms a second terminal of spiral inductor 312. Spiral inductor 314 is substantially similar in composition and formation to spiral inductor 312.

Surface mount components 316 and 318 can each comprise a passive component, such as a resistor, capacitor, or inductor. In one embodiment, surface mount components 316 and 318 and spiral inductors 312 and 314 form a balun circuit, where surface mount components 316 and 318 each comprise a capacitor.

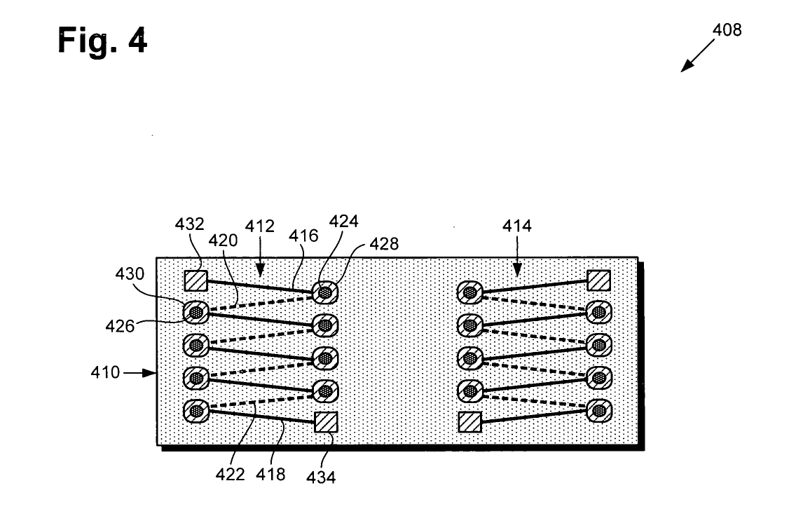

FIG. 4 shows a top view of integrated passive cap 408 in accordance with one embodiment of the present invention. Integrated passive cap 408 is an exemplary embodiment of the invention's integrated passive cap, such as integrated passive cap 108 in FIG. 1 or integrated passive cap 212 in FIG. 2. Integrated passive cap 408 includes cap substrate 410 and via winding inductors 412 and 414. Cap substrate 410 is substantially similar in composition and formation to cap substrate 107 in FIG. 1.

As shown in FIG. 4, via winding inductor 412 includes metal lines, such as metal lines 416 and 418, which are situated on the top surface of cap substrate 410, and metal lines, such as metal lines 420 and 422, which are situated on the bottom surface of cap substrate 410. Also shown in FIG. 4, via winding inductor 412 further includes conductive vias, such as conductive vias 424 and 426, which extend through cap substrate 410, and metal pads, such as metal pads 428 and 430, which are situated on the top surface of cap substrate 410. Via winding inductor 412 can also include metal pads (not shown in FIG. 4) on the bottom surface of cap substrate 410.

In via winding inductor 412, each metal line situated on the top surface of cap substrate 410 is coupled to a metal line on the bottom surface of cap substrate 410 by a conductive via. For example, metal line 416, which is situated on the top surface of cap substrate 410, is coupled to metal line 420, which is situated on the bottom surface of cap substrate 410, by conductive via 424. Each winding of via winding inductor 412 is formed by metal lines on the top and bottom surfaces of cap substrate 410 and two conductive vias. For example, metal lines 416 and 420 and conductive vias 424 and 426 form one winding of via winding inductor 412.

Further shown in FIG. 4, one end of metal line 416 is connected to cap bond pad 432, which forms a first terminal of via winding inductor 412, and one end of metal line 418 is connected to cap bond pad 434, which forms a second terminal of via winding inductor 412. Via winding inductor 414 is substantially similar in composition and formation to via winding inductor 412.

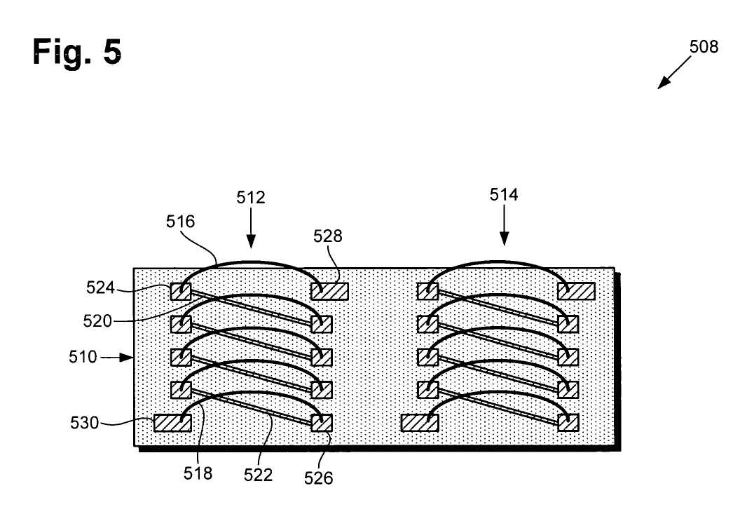

FIG. 5 shows a top view of integrated passive cap 508 in accordance with one embodiment of the present invention. Integrated passive cap 508 is an exemplary embodiment of the invention's integrated passive cap, such as integrated passive cap 108 in FIG. 1 or integrated passive cap 212 in FIG. 2. Integrated passive cap 508 includes cap substrate 510 and wire bond winding inductors 512 and 514. Cap substrate 510 is substantially similar in composition and formation to cap substrate 107 in FIG. 1 and cap substrate 213 in FIG. 2.

As shown in FIG. 5, wire bond winding inductors 512 and 514 are situated on the top surface of cap substrate 510. Wire bond winding inductor 512 includes wire bonds, such as wire bonds 516 and 518, metal lines, such as metal lines 520 and 522, and cap bond pads, such as cap bond pads 524 and 526. Also shown in FIG. 5, each metal line is coupled to a wire bond at a cap bond pad and each wire bond is coupled between two cap bond pads. For example, metal line 520 is coupled to wire bond 516 at cap bond pad 524 and wire bond 516 is coupled between cap bond pads 524 and 528. Each winding of wire bond winding inductor 512 is formed by a wire bond and a metal line that is coupled to the wire bond. For example, wire bond 516 and metal line 520 form one winding of wire bond winding inductor 512.

Further shown in FIG. 5, one end of wire bond 516 is bonded to cap bond pad 528, which forms a first terminal of wire bond winding inductor 512, and one end of wire bond 518 is bonded to cap bond pad 530, which forms a second terminal of wire bond winding inductor 512. Wire bond winding inductor 514 is substantially similar in composition and formation to wire bond winding inductor 512. Since wire bond winding inductors 512 and 514 are formed on the top surface of cap substrate 510, cap substrate 510 requires only one metal layer.

Thus, as discussed above, by providing a system-in-package that includes an integrated passive cap that is utilized to house one or more passive components and also utilized to form at least one air cavity over at least one semiconductor die, the invention advantageously achieves a system-in-package having a reduced footprint and reduced material and assembly costs compared to a conventional system-in-package. The invention's integrated passive cap can also include high performance passive components, such as inductors, which can be advantageous integrated in a cap substrate in the integrated passive cap.

From the above description of the invention it is manifest that various techniques can be used for implementing the concepts of the present invention without departing from its scope. Moreover, while the invention has been described with specific reference to certain embodiments, a person of ordinary skill in the art would appreciate that changes can be made in form and detail without departing from the spirit and the scope of the invention. Thus, the described embodiments are to be considered in all respects as illustrative and not restrictive. It should also be understood that the invention is not limited to the particular embodiments described herein but is capable of many rearrangements, modifications, and substitutions without departing from the scope of the invention.

Thus, an integrated passive cap in a system-in-package has been described.

1. A system-in-package comprising:
at least one semiconductor die situated over a package substrate;
a wall structure situated on said at least one semiconductor die;
an integrated passive cap situated over said wall structure, said integrated passive cap comprising at least one passive component;
said wall structure and said integrated passive cap forming an air cavity over said at least one semiconductor die.

2. The system-in-package of claim 1, wherein said integrated passive cap comprises at least one bond pad situated on a cap substrate.

3. The system-in-package of claim 2, wherein said at least one bond pad on said cap substrate is electrically connected to a substrate bond pad on said package substrate.

4. The system-in-package of claim 2, wherein said cap substrate comprises a material selected from the group consisting of a semiconductor, an organic laminate, and ceramic.

5. The system-in-package of claim 1, wherein said at least one passive component is selected from the group consisting of a spiral inductor, a via winding inductor, and a wire bond winding inductor.

6. The system-in-package of claim 1, wherein said at least one semiconductor die comprises a MEMS device.

7. The system-in-package of claim 1, wherein said at least one semiconductor die comprises a device selected from the group consisting of a BAW filter and a SAW filter.

8. The system-in-package of claim 1, wherein said wall structure comprises a polymer.

9. A system-in-package comprising:
a first and a second semiconductor die situated over a package substrate;
a first wall structure situated on said first semiconductor die and a second wall structure situated on said second semiconductor die;
an integrated passive cap situated over said first and second wall structures, said integrated passive cap comprising at least one passive component;
wherein said first wall structure and said integrated passive cap form a first air cavity over said first semiconductor die and said second wall structure and said integrated passive cap form a second air cavity over said second semiconductor die.

10. The system-in-package of claim 9, wherein said integrated passive cap comprises at least one bond pad situated on a cap substrate.

11. The system-in-package of claim 10, wherein said at least one bond pad on said cap substrate is electrically connected to a substrate bond pad on said package substrate.

12. The system-in-package of claim 10, wherein said cap substrate comprises a material selected from the group consisting of a semiconductor, an organic laminate, and ceramic.

13. The system-in-package of claim 9, wherein said at least one passive component is selected from the group consisting of a spiral inductor, a via winding inductor, and a wire bond winding inductor.

14. The system-in-package of claim 9, wherein at least one of said first and second semiconductor dies comprise a MEMS device.

15. The system-in-package of claim 9, wherein said first and second wall structures each comprise a polymer.

16. A method for forming a system-in-package, said method comprising:
attaching at least one semiconductor die to a package substrate;
forming a wall structure on said at least one semiconductor die;
covering said wall structure with an integrated passive cap, said integrated passive cap comprising at least one passive component;
wherein said integrated passive cap and said wall structure form an air cavity over said at least one semiconductor die.

17. The method of claim 16, wherein said integrated passive cap comprises at least one bond pad situated on a cap substrate.

18. The method of claim 17, wherein said at least one bond pad on said cap structure is electrically connected to a substrate bond pad on said package substrate.

19. The method of claim 17, wherein said cap substrate comprises a material selected from the group consisting of a semiconductor, an organic laminate, and ceramic.

20. The method of claim 1, wherein said at least one passive component is selected from the group consisting of a spiral inductor, a via winding inductor, and a wire bond winding inductor.
